(19) United States
(12) Patent Application Publication
(10) Pub. No.: US 2025/0357234 A1
(43) Pub. Date: Nov. 20, 2025

(54) PACKAGING OF DIES INCLUDING TSVs USING SACRIFICIAL CARRIER

(71) Applicant: Taiwan Semiconductor Manufacturing Co., Ltd., Hsinchu (TW)

(72) Inventors: Chien-Fu Tseng, Taipei City (TW); Der-Chyang Yeh, Hsinchu (TW); Hung-Pin Chang, New Taipei City (TW); Cheng-Hsien Hsieh, Kaohsiung City (TW); Li-Han Hsu, Hsinchu (TW); Meng-Tsan Lee, Hsinchu (TW); Wei-Cheng Wu, Hsinchu (TW); Chin-Te Wang, Taipei City (TW)

(21) Appl. No.: 19/283,442

(22) Filed: Jul. 29, 2025

Related U.S. Application Data
(63) Continuation of application No. 18/329,140, filed on Jun. 5, 2023.
(60) Provisional application No. 63/494,596, filed on Apr. 6, 2023.

(51) Int. Cl. H01L 23/31; H01L 21/56; H01L 21/683; H01L 21/768; H01L 23/00; H01L 23/48

(52) U.S. Cl. CPC H01L 23/3128; H01L 21/565; H01L 21/568; H01L 21/6835; H01L 21/76898; H01L 23/481; H01L 24/04; H01L 2221/68345; H01L 2224/04105; H01L 2924/18162

(57) ABSTRACT

A method includes bonding a composite die on a redistribution structure. The composite die comprises a device die including a semiconductor substrate, a through-semiconductor via penetrating through the semiconductor substrate, a metal via at a surface of the device die, and a sacrificial carrier attached to the device die. The composite die is encapsulated in an encapsulant. A planarization process is performed on the composite die and the encapsulant, and the sacrificial carrier is removed to reveal the metal via. A conductive feature is formed to electrically couple to the metal via.

### PRIORITY CLAIM AND CROSS-REFERENCE

This application is a continuation of U.S. patent application Ser. No. 18/329,140, filed on Jun. 5, 2023, and entitled “Packaging of Dies Including TSVs using Sacrificial Carrier,” which claims the benefit of the following provisionally filed U.S. Patent application: Application No. 63/494,596, filed on Apr. 6, 2023, and entitled “Package Structure and Method of Forming the Same,” which applications are hereby incorporated herein by reference.

### BACKGROUND

The packages of integrated circuits are becoming increasing complex, with more device dies integrated in the same package to achieve more functions. For example, a plurality of device dies such as processors and memory cubes may be bonded and integrated together. The package can include device dies formed using different technologies and have different functions, thus forming a system. This may save manufacturing cost and optimize device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-14 illustrate the cross-sectional views of intermediate stages in the formation of a package through face-to-back bonding in accordance with some embodiments.

FIGS. 15-26 illustrate the cross-sectional views of intermediate stages in the formation of a package through face-to-face bonding in accordance with some embodiments.

FIG. 27 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, the formation of the package includes forming a metal via electrically coupling to a through-semiconductor via, which penetrates through a semiconductor substrate of a device die. A sacrificial carrier is attached to the device die to form a composite die. The composite die may be encapsulated in an encapsulant, which is planarized to remove the sacrificial carrier and to reveal the metal via. The metal via is used as the buffer for the planarization process, so that in the planarization process, a thin dielectric isolation layer contacting the semiconductor substrate is not adversely removed or damaged.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

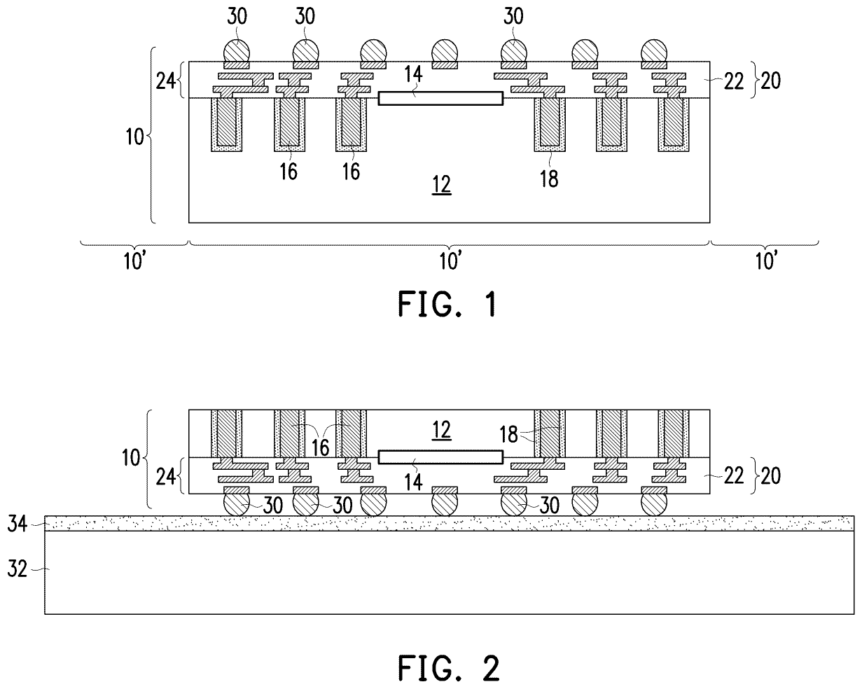

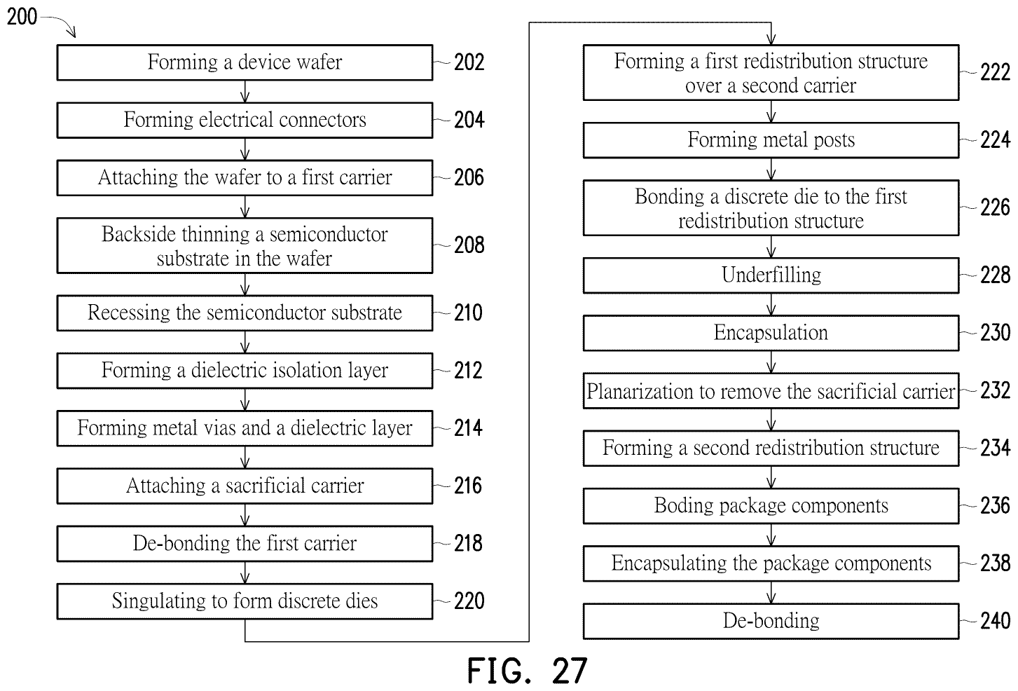

FIGS. 1 through 14 illustrate the cross-sectional views of intermediate stages in the formation of a package in accordance with some embodiments of the present disclosure. The corresponding processes are also reflected schematically in the process flow shown in FIG. 27.

FIG. 1 illustrates the formation of a device wafer in accordance with some embodiments. The respective process is illustrated as process 202 in the process flow 200 as shown in FIG. 27. Wafer 10 includes a plurality of device dies 10′ therein. Device wafer 10 includes substrate 12. In accordance with some embodiments, substrate 12 is a semiconductor substrate, which may include or be a crystalline silicon substrate, while it may also comprise or be formed of other semiconductor materials such as silicon germanium, carbon-doped silicon, or the like. In accordance with some embodiments, device dies 10′ include active circuits 14, which include active devices such as transistors (not shown) formed at the top surface of semiconductor substrate 12.

Through-vias (sometimes referred to as Through-Substrate Vias (TSVs)) 16 may be formed to extend into substrate 12 in accordance with some embodiments. TSVs 16 are also sometimes referred to as through-silicon vias when formed in a silicon substrate. Each of TSVs 16 may be encircled by dielectric isolation liners 18, which are formed of a dielectric material such as silicon oxide, silicon nitride, or the like. The isolation liners 18 electrically and physically isolate the respective TSVs 16 from semiconductor substrate 12. TSVs 16 and the isolation liners 18 extend from a top surface of semiconductor substrate 12 to an intermediate level between the top surface and the bottom surface of semiconductor substrate 12. In accordance with some embodiments, the top surfaces of TSVs 16 are level with the top surface of semiconductor substrate 12. In accordance with alternative embodiments, TSVs 16 extend into one of dielectric layers 22, and extend from a top surface of the corresponding dielectric layer 22 down into semiconductor substrate 12.

Interconnect structure 20 is formed over semiconductor substrate 12. Interconnect structure 20 may include a plurality of dielectrics layers 22 and conductive features 24 in the dielectric layers 22. The conductive features 24 may electrically connect to TSVs 16 and circuits 14.

In accordance with some embodiments, dielectric layers 22 are formed of silicon oxide, silicon nitride, silicon carbide, silicon oxynitride, combinations thereof, and/or multi-layers thereof. Dielectric layers 22 may comprise one or more Inter-Metal-Dielectric (IMD) layers formed of low-k dielectric materials having low k values, which may be, for example, lower than about 3.0, or in the range between about 2.5 and about 3.0. Dielectric layers 22 may also include passivation layers over the low-k dielectric layers, which passivation layers may be formed of non-low-k dielectric materials such as oxide, nitride, combinations thereof, and/or compositions thereof. Some of the upper ones of dielectric layers 22 may also comprise or may be formed of polymer(s) such as polybenzoxazole (PBO), polyimide, benzocyclobutene (BCB) or the like.

The conductive features 24 may include metal lines and vias, which may be formed in the low-k dielectric layers. The metal lines and vias may be formed using damascene processes in accordance with some embodiments. There may be some metal pads (such as aluminum copper pads) over the low-k dielectric layers and in the passivation layers and/or the non-low-k dielectric layers.

Electrical connectors 30 are formed at the top surface of device dies 10′. The respective process is illustrated as process 204 in the process flow 200 as shown in FIG. 27. In accordance with some embodiments, electrical connectors 30 comprise solder regions, metal pillars, metal pads, metal bumps (sometimes referred to as micro-bumps), or the like. The material of electrical connectors 30 may include non-solder materials, which may be formed of or comprise copper, nickel, aluminum, gold, multi-layers thereof, alloys thereof, or the like. Electrical connectors 30 may be electrically connected to integrated circuits 14.

Throughout the description, the side of semiconductor substrate 12 having the active circuits 14 and interconnect structure 20 is referred to as a front side (or active side) of semiconductor substrate 12, and the opposite side is referred to as a backside (or inactive side) of semiconductor substrate 12. Also, the front side of semiconductor substrate 12 is referred to as the front side (or active side) of wafer 10 and (device dies 10′), and the backside of semiconductor substrate 12 is also referred to as the backside (or inactive side) of device die 10′ (wafer 10).

Referring to FIG. 2, wafer 10 is attached to carrier 32 and release film 34. The respective process is illustrated as process 206 in the process flow 200 as shown in FIG. 27. Carrier 32 may be a glass carrier, a silicon wafer, an organic carrier, or the like. Carrier 32 may have a round top-view shape in accordance with some embodiments. Release film 34 may be formed of a polymer-based material and/or an epoxy-based thermal-release material (such as a Light-To-Heat-Conversion (LTHC) material), which is capable of being decomposed under radiation such as a laser beam, so that carrier 32 may be de-bonded from the overlying structure. In accordance with some embodiments of the present disclosure, release film 34 is applied on carrier 32 through coating.

Further referring to FIG. 2, a backside thinning process is performed from the backside of device wafer 10, and semiconductor substrate 12 is thinned. The respective process is illustrated as process 208 in the process flow 200 as shown in FIG. 27. The backside grinding process may be performed through a Chemical Mechanical Polish (CMP) process or a mechanical polishing process. TSVs 16 are exposed.

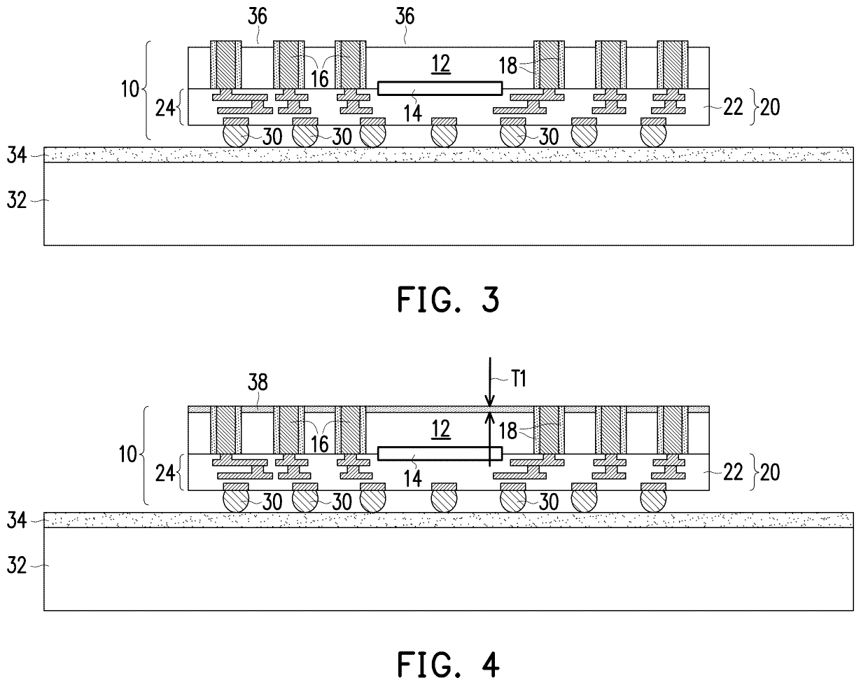

Next, referring to FIG. 3, semiconductor substrate 12 is recessed through an etch-back process. The respective process is illustrated as process 210 in the process flow 200 as shown in FIG. 27. Accordingly, the top portions of TSVs 16 protrude higher than the top surface (the back surface) of semiconductor substrate 12. In the recessing process, the dielectric isolation liners 18 may be recessed, for example, have top ends level with the top surface of semiconductor substrate 12, and hence the sidewalls of the protruding top portions of TSVs 16 are exposed. The space higher than the back surface of semiconductor substrate 12 and lower than the top ends of TSVs 16 are referred to as recesses 36. Alternatively, the dielectric isolation liners 18 are not recessed, and hence the protruding top portions of TSVs 16 are encircled by the corresponding top portions of dielectric isolation liners 18. The recessing depth of semiconductor substrate 12 may be in the range between about 0.5 μm and about 3 μm.

Referring to FIG. 4, recesses 36 are filled with dielectric isolation layer 38. The respective process is illustrated as process 212 in the process flow 200 as shown in FIG. 27. In accordance with some embodiments, dielectric isolation layer 38 is formed of or comprises an inorganic dielectric material such as silicon nitride, silicon oxynitride, silicon oxycarbonitride, silicon oxide, silicon carbide, silicon oxycarbide, or the like, or combinations thereof. The formation process may comprise a conformal or non-conformal deposition process, which may be performed using Atomic Layer Deposition (ALD), Chemical Vapor Deposition (CVD), Plasma-Enhanced Chemical Vapor Deposition (PECVD), or the like. Dielectric isolation layer 38 may also be deposited using a low-temperature deposition process. For example, when dielectric isolation layer 38 comprises silicon nitride, it may be deposited at a temperature in a range between about 300° C. and about 500° C. Dielectric isolation layer 38 may have thickness T1 in the range between about 0.5 μm and about 3 μm.

After the deposition, a planarization process is performed to remove the portions of dielectric isolation layer 38 higher than the top ends of TSVs 16. Accordingly, the top surface of dielectric isolation layer 38 is coplanar with the top ends of TSVs 16. The top portions of TSVs 16 are also encircled by dielectric isolation layer 38. In accordance with some embodiments, dielectric isolation liners 18 are not recessed when semiconductor substrate 12 is recessed. Accordingly, dielectric isolation layer 38 is separated from the top portions of TSVs 16 by the corresponding dielectric isolation liners 18. In accordance with alternative embodiments in which isolation liners 18 are recessed when semiconductor substrate 12 is recessed, dielectric isolation layer 38 is in physical contact with the top surfaces of TSVs 16.

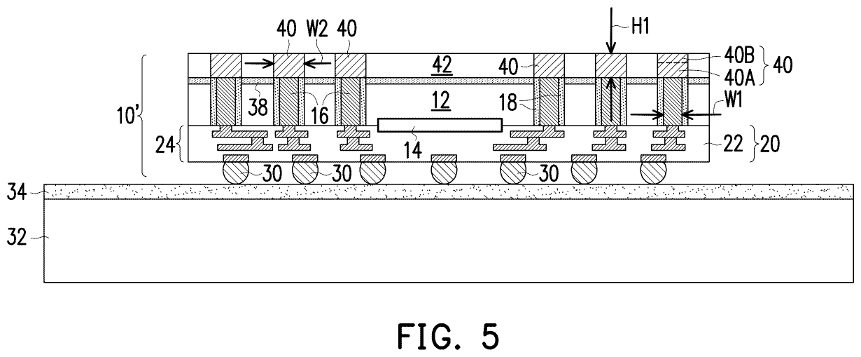

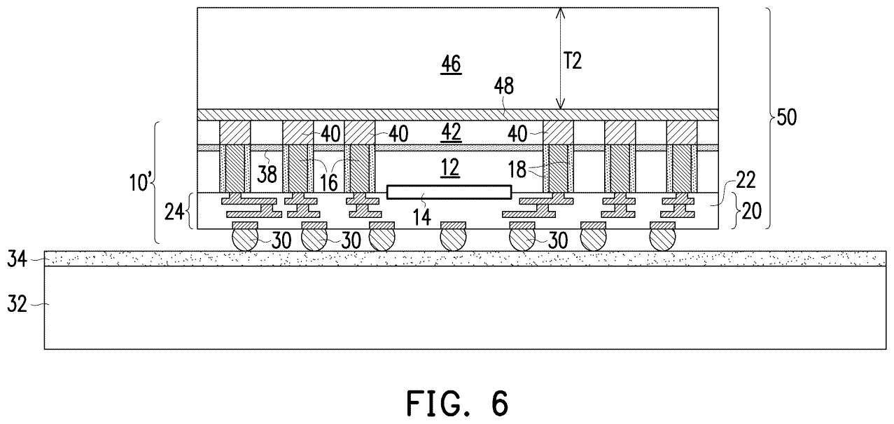

Referring to FIG. 5, a buffer structure including conductive vias 40 and dielectric layer 42 is formed. The respective process is illustrated as process 214 in the process flow 200 as shown in FIG. 27. In accordance with some embodiments, conductive vias 40 are metal vias, and are referred to as metal vias 40 hereinafter. The metal vias 40 may be formed of or comprise copper, aluminum, solder, nickel, tungsten, cobalt, palladium, titanium, titanium nitride, tantalum, tantalum nitride, or the like, or combinations thereof.

Dielectric layer 42 may comprise an inorganic material such as silicon oxide, silicon nitride, silicon carbide, silicon oxynitride, silicon oxycarbide, silicon oxycarbonitride, or the like, or combinations thereof. Alternatively, dielectric layer 42 may comprise an organic dielectric material such as PBO, polyimide, BCB, or the like. In accordance with some embodiments, the height H1 of dielectric layer 42 and metal vias 40 are in the range between about 10 μm and about 30 μm.

In accordance with some embodiments, the formation of metal vias 40 may comprise depositing a metal seed layer on the wafer 10 as shown in FIG. 4, forming and patterning a plating mask (not shown) such as a photoresist, and plating the respective metallic materials, as aforementioned, into the openings. The metal seed layer may comprise a titanium layer and a copper layer over the titanium layer, or may be a copper layer. The plating mask is then removed, followed by etching the exposed portions of the metal seed layer. Accordingly, the sidewalls of the metal vias 40 are vertical and straight within process variation. Dielectric layer 42 may then be formed, followed by a planarization process to level the top surface of dielectric layer 42 with the top ends of metal vias 40.

Alternatively, after the planarization, metal vias 40 are covered by dielectric layer 42. When plated, metal vias 40 may also include non-solder lower portions 40A, which are formed of the precedingly discussed non-solder materials, and solder layers 40B over the respective non-solder lower portions. Solder layers 40B are softer than the non-solder lower portions 40A, and are more suitable for probing. Alternatively, the plated material is a homogeneous material such as copper, a copper alloy, tungsten, or the like.

In accordance with alternative embodiments, metal vias 40 are formed through a damascene process. The formation process may include depositing dielectric layer 42, and then patterning dielectric layer 42 to reveal the underlying TSVs 16, and possibly dielectric isolation layer 38 and dielectric isolation liners 18. Dielectric isolation liners 18 may be or may not be revealed, depending on whether they are recessed during the formation of recesses 36 (FIG. 3).

A conductive layer(s) is then deposited. In accordance with some embodiments, each of metal vias 40 includes a conformal diffusion barrier layer (also referred to as an adhesion layer), which may include titanium, titanium nitride, tantalum, tantalum nitride, or other alternatives. An inner conductive material is deposited over the adhesion layer, and may include a metallic material such as copper, a copper alloy, silver, gold, tungsten, aluminum, or the like. A planarization process such as a CMP process may be performed to level the surface of the conductive materials, leaving metal vias 40 in dielectric layer 42.

In accordance with some embodiments, the width W2 of metal vias 40 may be greater than, equal to, or smaller than the width W1 of TSVs 16. In FIG. 5, the thickness of dielectric isolation liners 18 may be exaggerated, and the thickness of dielectric isolation liners 18 may be much smaller than width W1 of TSVs 16. Metal vias 40 may also be in physical contact with the top ends of dielectric isolation liners 18, or may be spaced apart from the top ends of dielectric isolation liners 18 by dielectric isolation liners 38, depending on whether dielectric isolation liners 18 have been recessed or not.

FIG. 6 illustrates the attachment of sacrificial carrier 46 to wafer 10. The attachment may be performed through adhesion film 48. The respective process is illustrated as process 216 in the process flow 200 as shown in FIG. 27. Wafer 10, which was thinned in preceding processes, may be too thin for subsequent processes, and may suffer from breakage and/or warpage. For example, the thickness of wafer 10 may be in the range between about 30 μm and about 50 μm. Sacrificial carrier 46 may thus provide mechanical support. In accordance with some embodiments, sacrificial carrier 46 is formed of or comprises a silicon wafer, a glass wafer, or the like. Sacrificial carrier 46 may also be an inorganic or an organic carrier. The thickness T2 of sacrificial carrier 46 is great enough for providing support to wafer 10 and the device dies 10′ in subsequent processes, and not overly thick since it will be removed through grinding or CMP. In accordance with some embodiments, the thickness T2 of sacrificial carrier 46 may be in the range between about 500 μm and about 700 μm. Throughout the description, the structure including wafer 10 and the sacrificial carrier 46 are collectively referred to as composite wafer 50.

In accordance with some embodiments, sacrificial carrier 46 is thinned in a backside grinding process to a suitable thickness, so it is adequate to provide support to wafer 10, but is not too thick. In accordance with alternative embodiments, no thinning of sacrificial carrier 46 is performed.

The composite wafer 50 is then de-bonded from carrier 32, for example, by projecting UV light or a laser beam, which penetrates through carrier 32 and is projected on release film 34. The respective process is illustrated as process 218 in the process flow 200 as shown in FIG. 27. Release film 34 is decomposed under the heat of the UV light or the laser beam. The composite wafer 50 may then be separated from carrier 32.

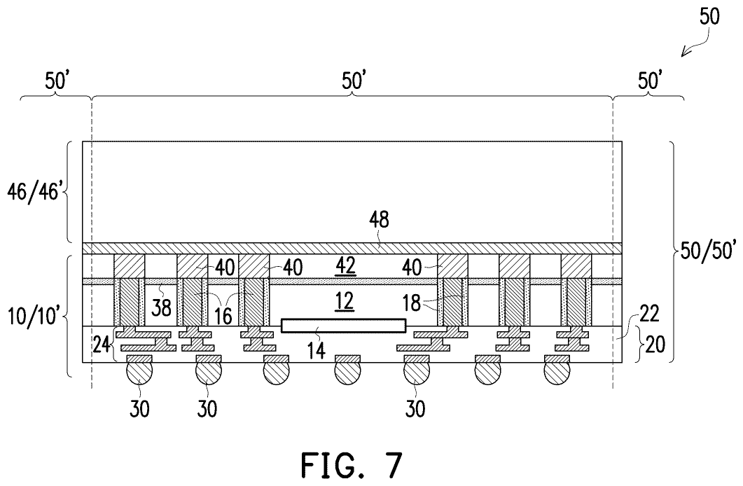

In a subsequent process, as shown in FIG. 7, composite wafer 50 is singulated, for example, sawed into a plurality of discrete dies 50′, which are referred to as composite dies 50′. The respective process is illustrated as process 220 in the process flow 200 as shown in FIG. 27. In the sawing process, composite wafer 50 may be fixed on a dicing tape (not shown), which is further fixed on a frame (not shown). Each of composite dies 50′ includes carrier die 46′, which is a blank die cut from carrier 46, and device die 10′, which is a part of wafer 10.

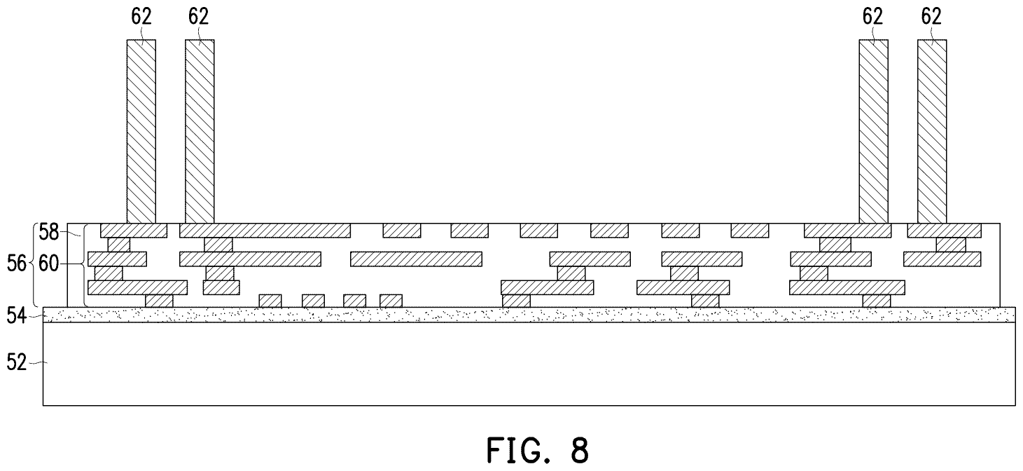

FIGS. 8 through 11 illustrate the packaging of discrete dies 10′ in accordance with some embodiments. Referring to FIG. 8, carrier 52 is provided, with release film 54 being coated on carrier 52. Carrier 52 may be a glass carrier, a silicon wafer, an organic carrier, or the like. Release film 54 may be formed of a polymer-based material and/or an epoxy-based thermal-release material, such as a LTHC material. There may be a buffer dielectric layer (not shown) such as a PBO layer formed on release film 54.

Redistribution structure 56, which includes a plurality of dielectric layers 58 and a plurality of RDLs 60, is formed over the release film 54. The respective process is illustrated as process 222 in the process flow 200 as shown in FIG. 27. Redistribution structure 56 is alternatively referred to as interposer 56. In accordance with some embodiments, redistribution structure 56 is pre-formed, and the pre-formed redistribution structure 56 is placed on release film 54. Redistribution structure 56 may be an organic interposer comprising organic dielectric layers 58 and redistribution lines 60.

In accordance with alternative embodiments, redistribution structure 56 is formed on carrier 52 layer-by-layer. For example, the formation of RDLs 60 may include forming a dielectric layer 58, and forming openings in dielectric layer 58 through a patterning process. A metal seed layer (not shown) is deposited, which includes some portions over, and some other portions extending into dielectric layer 58. Dielectric layers 58 may be formed of or comprise an organic material such as PBO, polyimide, BCB, or the like, or inorganic materials such as silicon oxide, silicon nitride, or the like. A patterned mask (not shown) such as a photoresist is then formed over the metal seed layer, followed by a metal plating process to deposit a metallic material on the exposed metal seed layer. The patterned mask and the portions of the metal seed layer covered by the patterned mask are then removed, leaving a layer of RDLs 60.

In accordance with some embodiments, the metal seed layer includes a titanium layer and a copper layer over the titanium layer. The metal seed layer may be formed using, for example, Physical Vapor Deposition (PVD) or a like process. The plated material may include copper, aluminum, cobalt, nickel, gold, silver, tungsten, or alloys thereof. The plating may be performed using, for example, an electrochemical plating process. The dielectric layers 58 and RDLs 60 are formed layer-by-layer, and collectively forming redistribution structure 56.

Metal posts 62 are then formed. The respective process is illustrated as process 224 in the process flow 200 as shown in FIG. 27. In accordance with some embodiments, the formation process includes depositing a metal seed layer, forming and patterning a plating mask such as a photoresist, plating a metallic material in the plating mask, removing the plating mask, and removing the portions of the metal seed layer previously covered by the plating mask. The plated metallic material and the remaining portions of the metal seed layer are collectively referred to as metal posts 62.

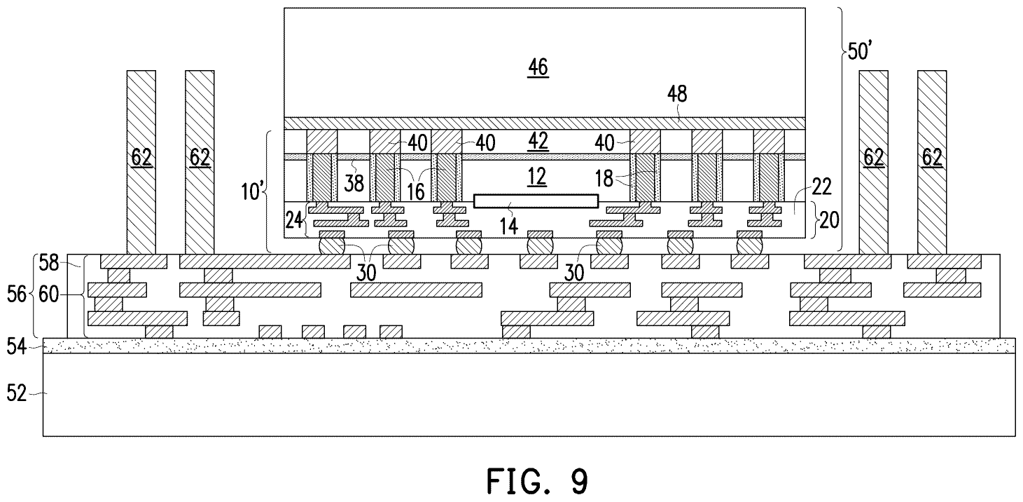

Next as shown in FIG. 9, composite die 50′ is bonded to redistribution structure 56, for example, through electrical connectors 30, which are bonded to the metal pads, metal pillars, or the like in redistribution structure 56. The respective process is illustrated as process 226 in the process flow 200 as shown in FIG. 27. Although one composite die 50′ is illustrated, there may be a plurality of composite dies 50′ bonded over the same carrier 52. The front side of device die 10′ faces redistribution structure 56.

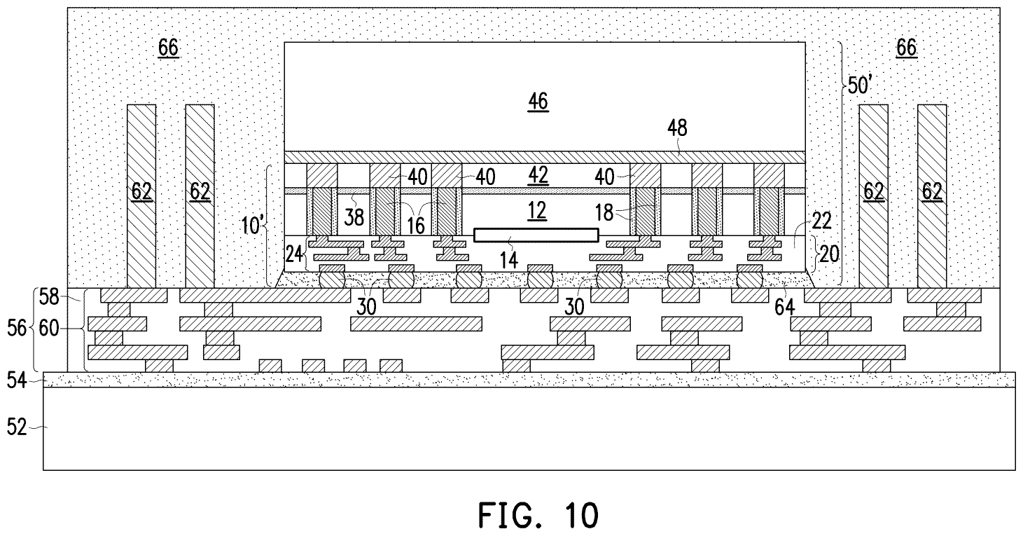

Referring to FIG. 10, underfill 64 is dispensed into the gap between die 10′ and redistribution structure 56. The respective process is illustrated as process 228 in the process flow 200 as shown in FIG. 27. Next, composite die 50′ and metal posts 62 are encapsulated in encapsulant 66. Encapsulant 66 fills the gaps between neighboring metal posts 62 and the gaps between metal posts 62 and composite die 50′. The respective process is illustrated as process 230 in the process flow 200 as shown in FIG. 27. Encapsulant 66 may include a molding compound, a molding underfill, an epoxy, and/or a resin. The top surface of encapsulant 66 may be higher than the top surface of sacrificial die 46′. When formed of molding compound, encapsulant 66 may include a base material, which may be a polymer, a resin, an epoxy, or the like, and filler particles in the base material. The filler particles may be dielectric particles of SiO₂, Al₂O₃, silica, or the like, and may have spherical shapes. Also, the spherical filler particles may have a plurality of different diameters.

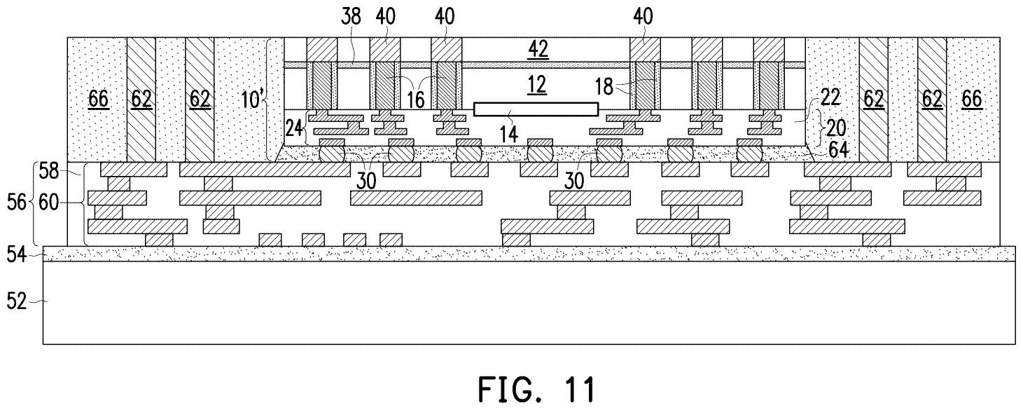

In a subsequent process, as shown in FIG. 11, a planarization process such as a CMP process or a mechanical grinding process is performed to thin encapsulant 66 and composite die 50′, until metal posts 62 are exposed and sacrificial die 46′ is removed. The respective process is illustrated as process 232 in the process flow 200 as shown in FIG. 27. Metal posts 62 are alternatively referred to as through-vias 62 hereinafter since they penetrate through encapsulant 66.

In the planarization process, sacrificial die 46′ is removed, and adhesion film 48 is also removed, hence exposing the underlying metal vias 40. Sacrificial wafer 46 (FIG. 6) is used to support the sawing of the thin wafer 10 (FIG. 7) when the thin wafer 10 is de-bonded from carrier 32, and provides mechanical support during the bonding of thin die 10′ to redistribution structure 56.

It is appreciated that the planarization of encapsulant 66 may have a variation greater than the thickness of dielectric isolation layer 38. For example, the variation of the thinning of encapsulant 66 may be in the range between +3 μm and −3 μm, while the thickness of dielectric isolation layer 38 may be in the range between about 0.5 μm and about 3 μm. If metal vias 40 are not formed, in order to reveal TSVs 16 through the planarization process, the planarization process is difficult to control. There is the likelihood that dielectric isolation layer 38 may be adversely removed due to the not-well-controlled polishing process, and the subsequently formed conductive features for connecting to the through-vias may be in contact with the back surface of (and are electrically shorted to) semiconductor substrate 12. In accordance with the embodiments of the present application, the thickness of metal vias 40 is greater than the process variation with adequate margin, and metal vias 40 can be used as a buffer. Even if out-of-specification variation occurs in the planarization of encapsulant 66, it is ensured that the overlying structure will not be electrically shorted to semiconductor substrate 12.

In accordance with some embodiments in which metal vias 40 comprise solder regions 40B (FIG. 5, for example), due to the large variation in the planarization process, different device dies 10′ on the same carrier may be polished with different amount, and some of metal vias 40 in one device die 10′ may be polished more than the metal vias 40 in other device dies 10′. The resulting metal vias 40 in different dies 10′ may thus have a different remaining thickness than the metal vias 40 in other dies 10′. In the embodiments in which metal vias 40 have different layers, some layers may be fully removed from some of the dies 10′, while left unremoved in other dies 10′, or removed from some metal vias in a die 10′, while left unremoved in other metal vias 40 in the same die 10′. For example, when metal vias comprise non-solder metal layers 40A and solder layers 40B, the solder layers 40B may be removed from some, while left in other dies 10′, or removed from some metal vias 40, while left in other metal vias 40 in the same die 10′.

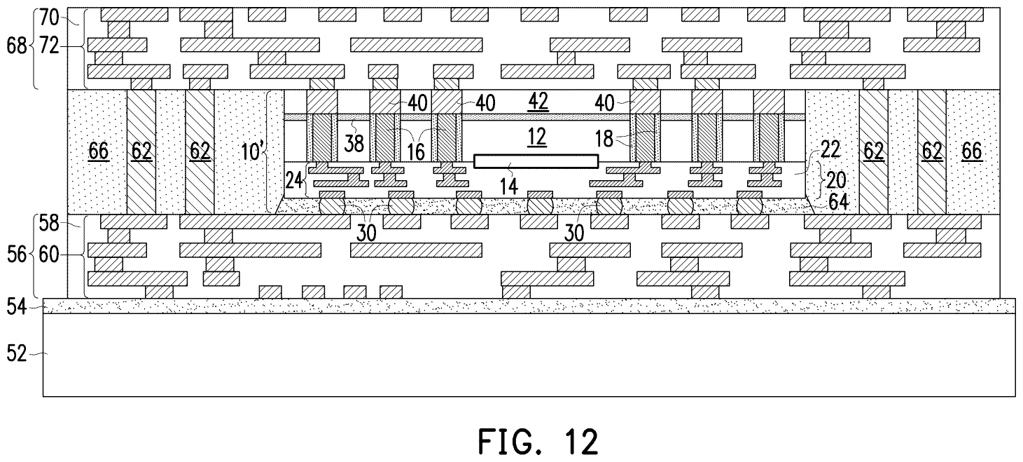

FIG. 12 illustrates the formation of redistribution structure 68, which includes dielectric layers 70 and RDLs 72 in dielectric layers 70. The respective process is illustrated as process 234 in the process flow 200 as shown in FIG. 27. The materials, the structures, and the formation process may be similar to or the same as that of redistribution structure 56, and are not repeated herein.

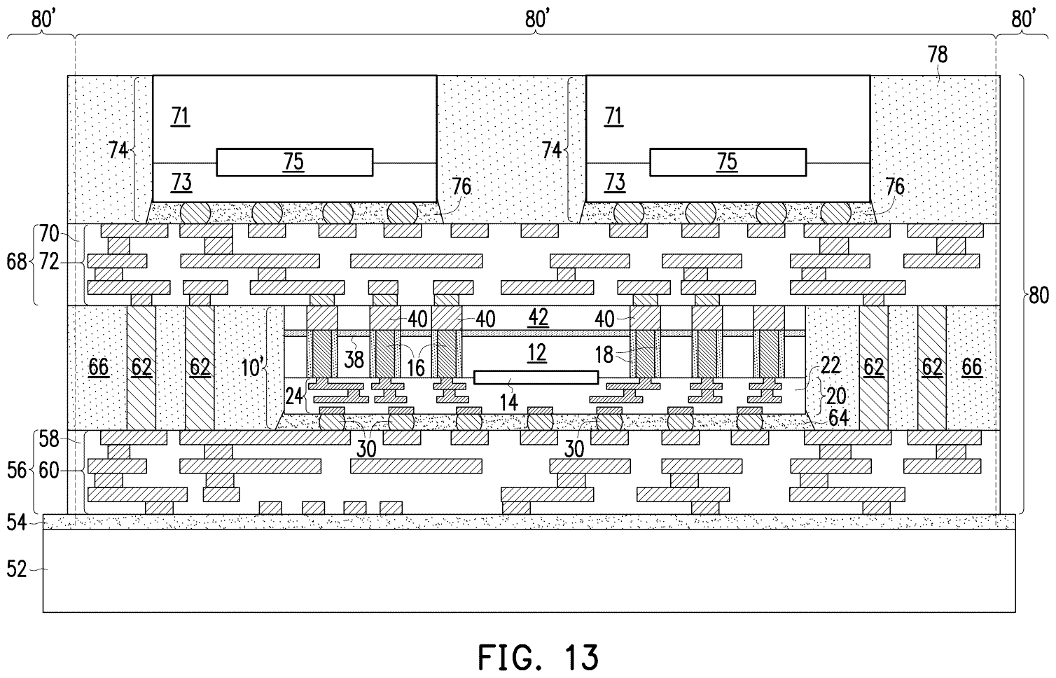

FIG. 13 illustrates the bonding of package components 74 to redistribution structure 68 in accordance with some embodiments. The respective process is illustrated as process 236 in the process flow 200 as shown in FIG. 27. Since the front sides of package components 74 faces the backside of device dies 10′, the bonding is referred to as face-to-back bonding. Package components 74 may include device dies, multi-die stacks, packages, or the like. In accordance with some embodiments, package components 74 are device dies, and include semiconductor substrates 71 and interconnect structures 73. Integrated circuit devices 75 are formed on the front sides of semiconductor substrates 71. Underfill 76 is dispensed into the gaps between the package components 74 and the underlying redistribution structure 68. Encapsulant 78 is then dispensed, cured, and planarized. The respective process is illustrated as process 238 in the process flow 200 as shown in FIG. 27. The structure over release film 54 is referred to as reconstructed wafer 80. Next, reconstructed wafer 80 is de-bonded from carrier 52. The respective process is illustrated as process 240 in the process flow 200 as shown in FIG. 27. Reconstructed wafer 80 is singulated to form a plurality of packages 80′.

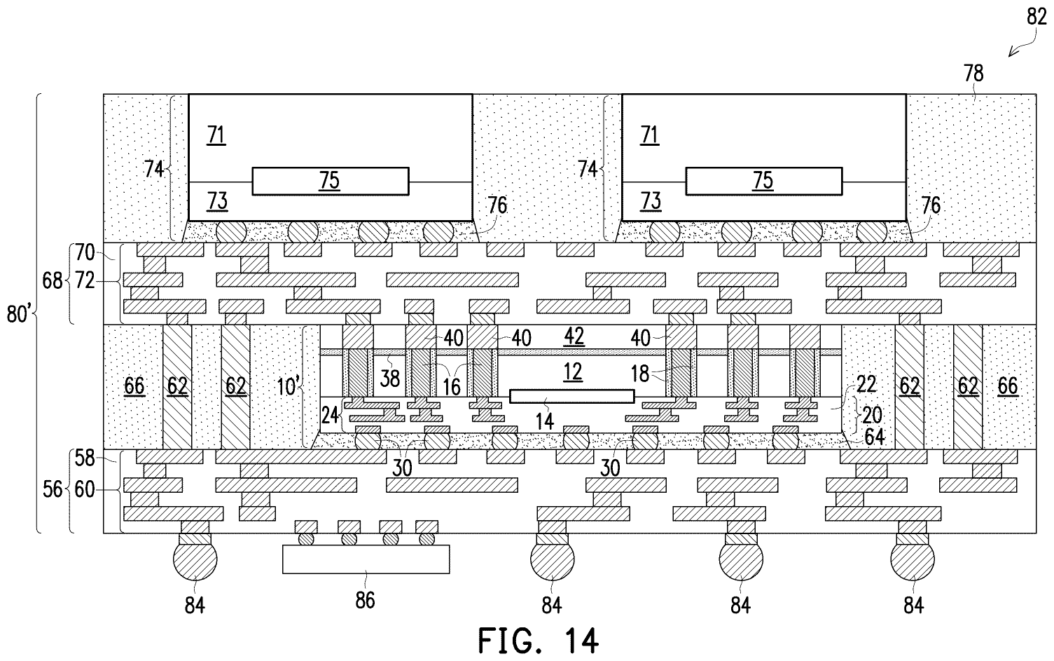

More processes may be performed on package 80′ (either before or after the singulation of the reconstructed wafer 80) to form package 82, as shown in FIG. 14. For example, solder regions 84 may be formed on redistribution structure 56, and discrete dies such as Independent Passive Devices (IPD) dies 86 may be bonded to redistribution structure 56.

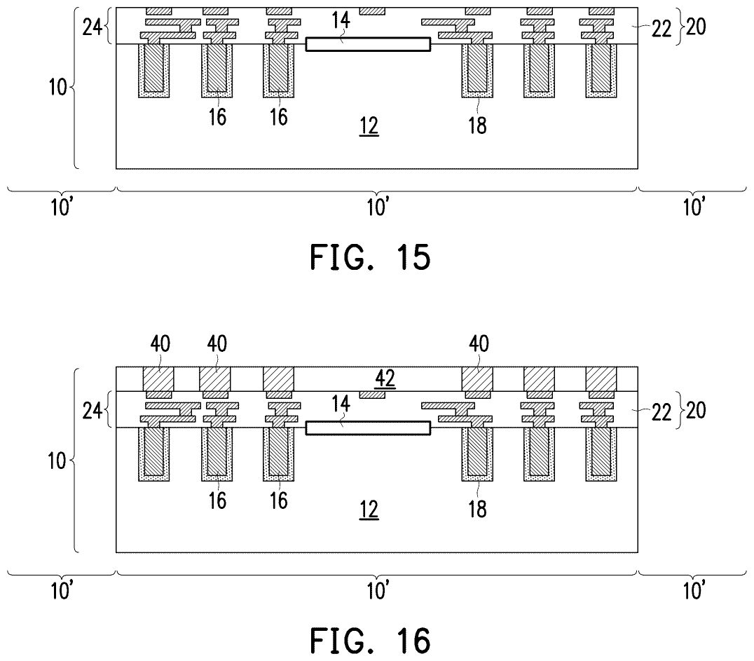

FIGS. 15 through 26 illustrate the cross-sectional views of intermediate stages in the formation of a package in accordance with alternative embodiments of the present disclosure. These embodiments are similar to the embodiments as shown in FIGS. 1 through 14, except that the buffer structure including metal vias 40 and dielectric layer 42 are formed on the front side, rather than on the back side of wafer 10 and device die 10′. As a result, face-to-face bonding is adopted when package components 74 are bonded. Unless specified otherwise, the materials, the structures, and the formation processes of the components in these embodiments are essentially the same as the like components denoted by like reference numerals in the preceding embodiments. The details regarding the materials, the structures, and the formation processes of the components shown in FIGS. 15 through 26 may thus be found in the discussion of the preceding embodiments.

Referring to FIG. 15, wafer 10, which includes device dies 10′, is formed. TSVs 16 are also formed, and extend into semiconductor substrate 12. Next, as shown in FIG. 16, metal vias 40 and dielectric layer 42 are formed on the front side (rather than on the backside) of wafer 10. Metal vias 40 are electrically connected to integrated circuits 14 and through-vias 16. The formation process, the structures, and materials of metal vias 40 and dielectric layer 42 may be found referring to the discussion of FIG. 5, and are not repeated herein.

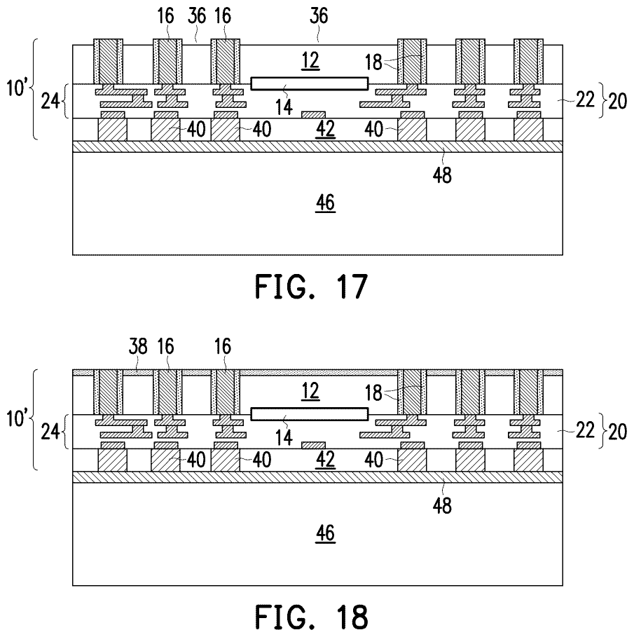

Next, as shown in FIG. 17, the front side of wafer 10 is adhered to sacrificial carrier 46 through adhesion film 48. A backside thinning process is performed to remove the back portion of semiconductor substrate 12, and to reveal TSVs 16. A recessing process is then performed to recess TSVs 16, and to form recesses 36. Again, dielectric isolation liners 18 may be recessed, or may not be recessed.

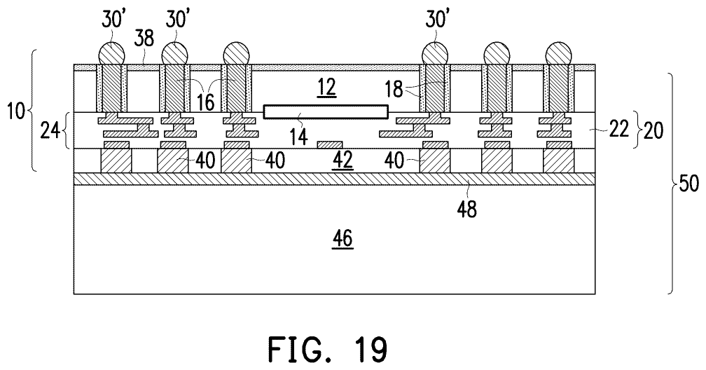

FIG. 18 illustrates the formation of dielectric isolation layer 38 to fill recesses 36, and TSVs 16 are exposed through dielectric isolation layer 38. Next, referring to FIG. 19, electrical connectors 30′ are formed on TSVs 16. Composite wafer 50 is thus formed. In accordance with some embodiments, electrical connectors 30′ are solder regions, and the formation process may include placing solder balls on TSVs 16, and performing a reflow process. In accordance with alternative embodiments, electrical connectors 30′ may include metal pillars (non-solder metal pillars), which may be formed using essentially the same plating process for forming metal vias 40 as discussed in preceding paragraphs. The respective electrical connectors 30′ may or may not include solder layers on the metal pillars. Electrical connectors 30′ may be wider than the respective underlying TSVs 16, and dielectric isolation layer 38 may electrically insulate electrical connectors 30′ from semiconductor substrate 12.

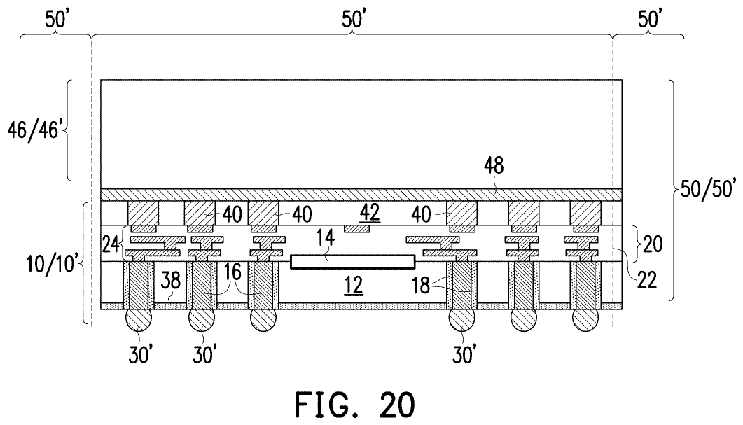

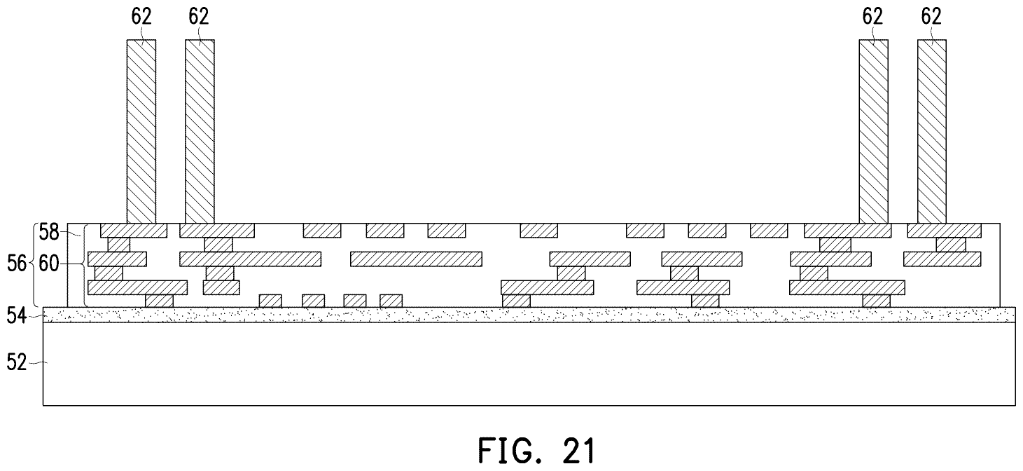

Next, as shown in FIG. 20, a singulation process is performed to saw composite wafer 50 into composite dies 50′. Composite dies 50′ include sacrificial dies 46′ and device dies 10′. FIG. 21 illustrates the formation of redistribution structure 56 on carrier 52 and release film 54. Metal posts 62 are also formed.

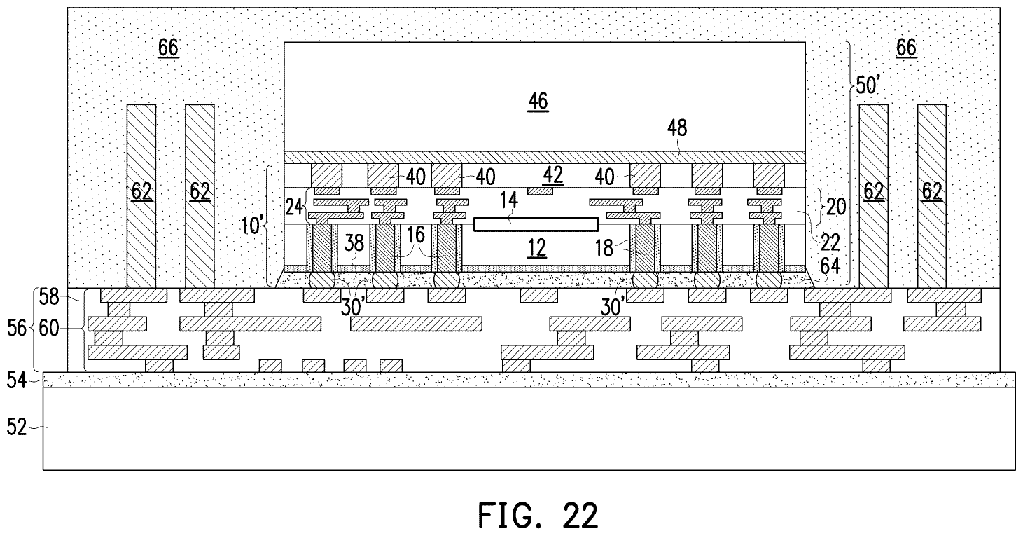

Next, as shown in FIG. 22, composite die 50′ is bonded to redistribution structure 56. Although one die 50′ is illustrated, there may be a plurality of dies 50′ bonded over redistribution structure 56. In accordance with these embodiments, the backside (rather than the front side) of device die 10′ faces redistribution structure 56.

Underfill 64 is then dispensed into the gap between die 10′ and redistribution structure 56. Next, composite die 50′ and metal posts 62 are encapsulated in encapsulant 66. The top surface of encapsulant 66 may be higher than the top surface of sacrificial die 46′.

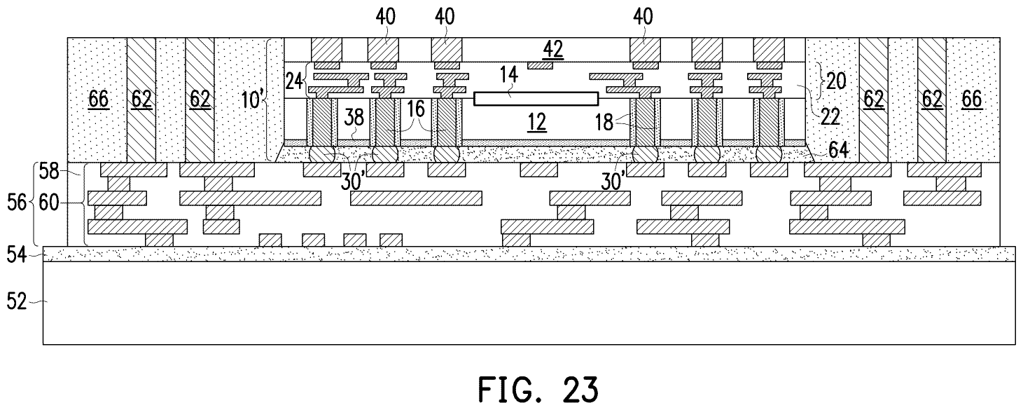

In a subsequent step, as shown in FIG. 23, a planarization process such as a CMP process or a mechanical grinding process is performed to thin encapsulant 66, until metal posts 62 and metal vias 40 are exposed. In the planarization process, sacrificial die 46′ and adhesion film 48 (FIG. 22) are removed.

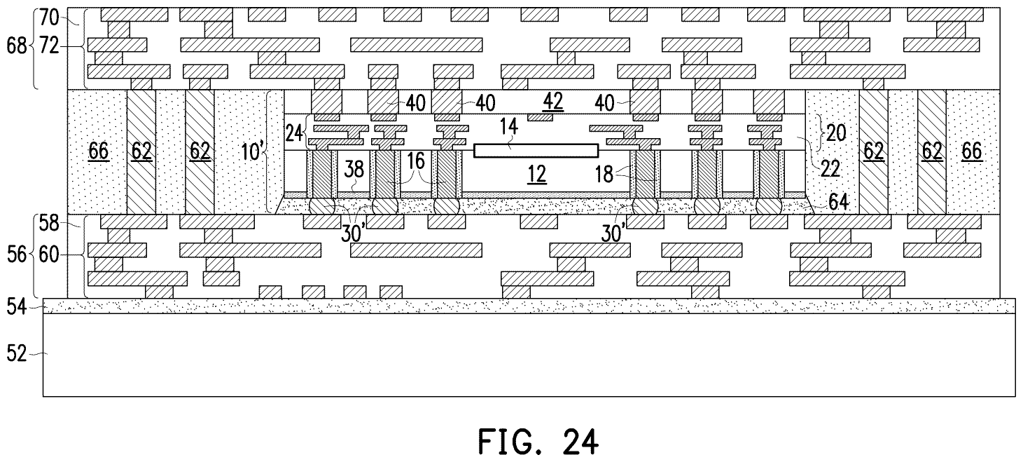

FIG. 24 illustrates the formation of redistribution structure 68, which includes dielectric layers 70 and RDLs 72 in dielectric layers 70.

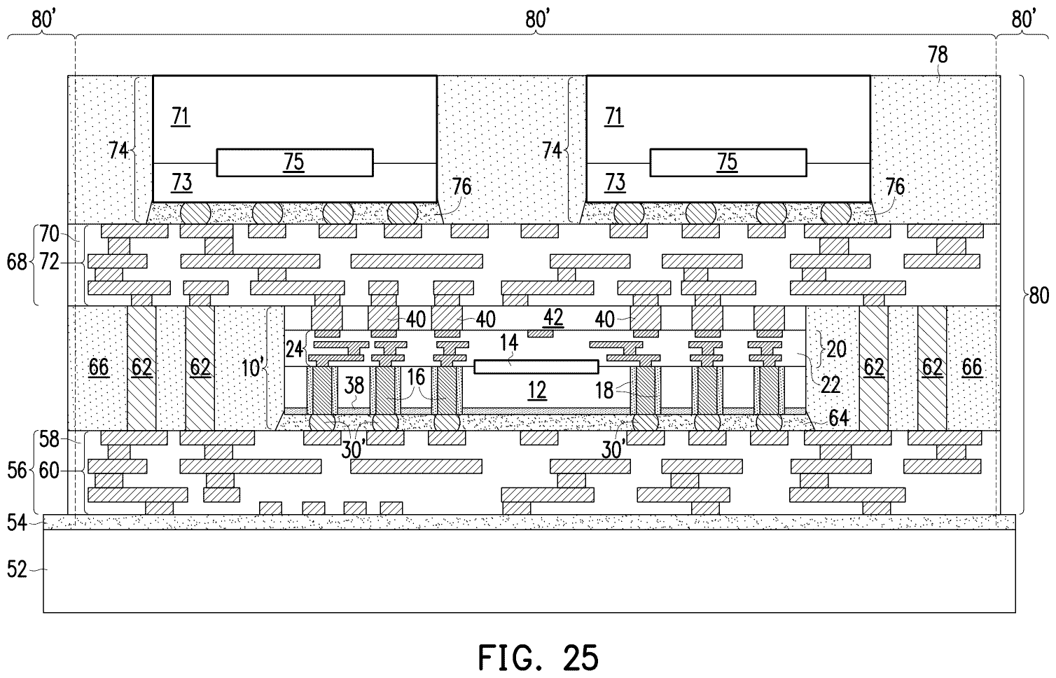

FIG. 25 illustrates the bonding of package components 74 to redistribution structure 68 in accordance with some embodiments. Since the front sides of package components 74 face the front side of device dies 10′, the bonding is referred to as face-to-face bonding. Underfill 76 is dispensed into the gaps between the package components 74 and the underlying redistribution structure 68. Encapsulant 78 is then dispensed, cured, and planarized. The structure over release film 54 is referred to as reconstructed wafer 80. Next, reconstructed wafer 80 is singulated to form a plurality of packages 80′.

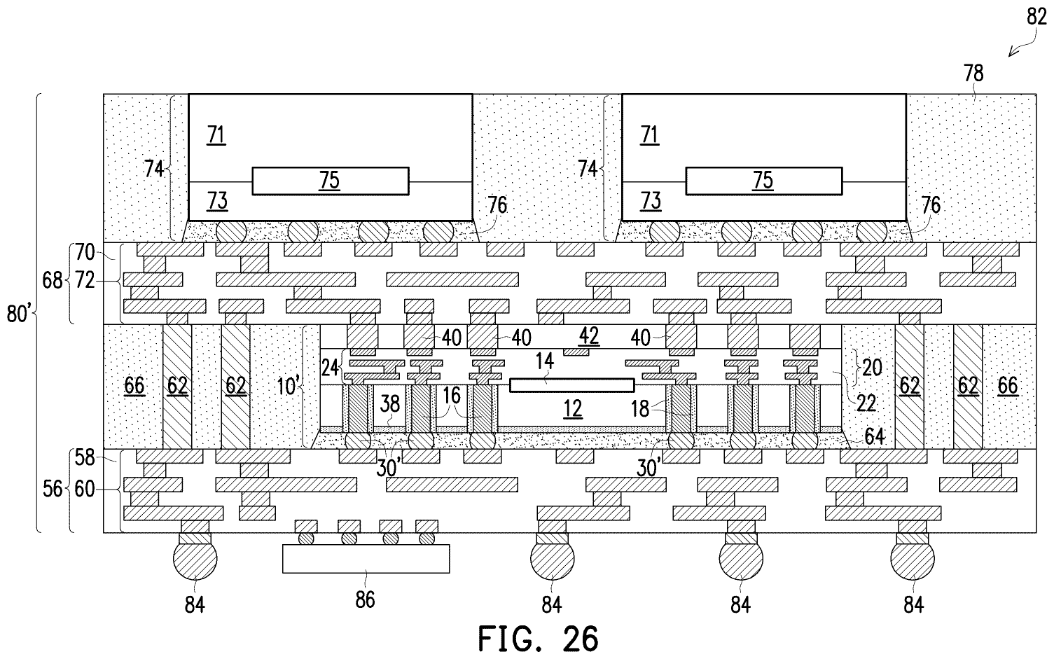

FIG. 26 illustrates the formation of package 82 in accordance with some embodiments, which may include the formation of electrical connectors 84 and the bonding of IPD dies 86.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming metal vias on TSV dies that include TSVs therein, when the TSV dies are encapsulated in an encapsulant, the metal vias may be used as a buffer structure, so that the variation in the planarization of the encapsulant will at most result in the thinning of the metal vias. The thinning of the metal vias will not adversely affect the yield of the resulting package. As a comparison, if no metal vias are formed. The dielectric isolation layer may be adversely thinned or removed. This may cause the electrical shorting of the subsequent formed conductive features to the semiconductor substrate in the TSV die. In addition, a piece of sacrificial carrier may be encapsulated into the encapsulant, and removed in the planarization process. Accordingly, the sacrificial carrier may mechanically support the device die/wafer until the device die is bonded and encapsulated, so that maximum support may be provided.

In accordance with some embodiments of the present disclosure, a method comprises bonding a composite die on a redistribution structure, wherein the composite die comprises a device die comprising a semiconductor substrate; and a through-semiconductor via penetrating through the semiconductor substrate; a metal via at a surface of the device die; and a sacrificial carrier attached to the device die; encapsulating the composite die in an encapsulant; performing a planarization process on the composite die and the encapsulant, wherein the sacrificial carrier is removed to reveal the metal via; and forming a conductive feature electrically coupling to the metal via. In an embodiment, the metal via is on a backside of the device die, and is in contact with the through-semiconductor via.

In an embodiment, the method further comprises performing a backside thinning process to thin the semiconductor substrate, so that the through-semiconductor via is revealed; recessing the semiconductor substrate, so that a protruding portion of the through-semiconductor via protrudes out of the semiconductor substrate; and forming a dielectric isolation layer to encircle the protruding portion of the through-semiconductor via. In an embodiment, the metal via laterally extends beyond respective edges of the through-semiconductor via, and contacts the dielectric isolation layer. In an embodiment, the dielectric isolation layer comprises silicon nitride. In an embodiment, the metal via is on a front side of the device die.

In an embodiment, the method further comprises performing a backside thinning process to thin the semiconductor substrate, so that the through-semiconductor via is revealed; recessing the semiconductor substrate, so that a protruding portion of the through-semiconductor via protrudes out of the semiconductor substrate; forming a dielectric isolation layer to encircle the protruding portion of the through-semiconductor via; and forming a solder region contacting the through-semiconductor via. In an embodiment, the sacrificial carrier is attached to the device die through an adhesion film, and wherein the adhesion film is removed in the planarization process. In an embodiment, the method further comprises forming a plurality of metal posts, wherein the encapsulant further encapsulates the plurality of metal posts therein, and wherein after the planarization process, the plurality of metal posts are revealed.

In an embodiment, the method further comprises forming an interconnect structure, wherein the composite die is bonded to the interconnect structure, and wherein the plurality of metal posts are formed starting from the interconnect structure. In an embodiment, the method further comprises attaching the sacrificial carrier to a device wafer comprising the device die therein to form a composite wafer; and singulating the composite wafer as a plurality of composite dies, with the composite die being one of the plurality of composite dies.

In accordance with some embodiments of the present disclosure, a method comprises forming a device wafer comprising performing a backside grinding process on a backside of a semiconductor substrate, so that a through-via is revealed from the backside of the semiconductor substrate; recessing the semiconductor substrate from the backside, wherein a portion of the through-via protrudes out of the semiconductor substrate; forming a dielectric isolation layer on a back surface of the semiconductor substrate, wherein the through-via is revealed through the dielectric isolation layer; forming a metal via contacting the through-via; and forming a dielectric layer, wherein the metal via is in the dielectric layer; attaching a sacrificial carrier to the device wafer to form a composite wafer; and sawing the composite wafer into a plurality of composite dies, wherein the sacrificial carrier is also sawed as sacrificial dies.

In an embodiment, the method further comprises bonding a discrete composite die in the plurality of composite dies to a redistribution structure; encapsulating the discrete composite die in an encapsulant; and polishing the discrete composite die and the encapsulant until a sacrificial die in the discrete composite die is removed. In an embodiment, after the polishing, the metal via is revealed, and wherein the method further comprises forming a redistribution line connecting to the metal via. In an embodiment, the method further comprises, before the sawing the composite wafer, thinning the sacrificial carrier. In an embodiment, the forming the dielectric isolation layer comprises a low-temperature deposition process to deposit a silicon nitride layer.

In accordance with some embodiments of the present disclosure, a method comprises forming a package comprising forming a first redistribution structure; and bonding a device die over the first redistribution structure, wherein the device die comprises a semiconductor substrate; an integrated circuit at a front surface of the semiconductor substrate; a dielectric isolation layer contacting a back surface of the semiconductor substrate; a through-via penetrating through the semiconductor substrate and the dielectric isolation layer; and a metal via contacting the through-via; and forming a second redistribution structure over the device die, wherein the first second redistribution is electrically connected to the second redistribution through the through-via.

In an embodiment, the method further comprises encapsulating the device die in an encapsulant, wherein when the device die is encapsulated, the device die is attached to a sacrificial carrier; and polishing the encapsulant, wherein the sacrificial carrier is removed during the polishing. In an embodiment, the metal via extends laterally beyond respective edges of the through-via, and the metal via physically contacts the dielectric isolation layer. In an embodiment, the dielectric isolation layer comprises an inorganic dielectric material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
encapsulating a composite die in an encapsulant, wherein the composite die comprises:
a semiconductor substrate;
an integrated circuit at a surface of the semiconductor substrate;
a metal via electrically coupled to the integrated circuit; and
a sacrificial carrier attached to the metal via;
performing a planarization process on the composite die and the encapsulant, wherein the sacrificial carrier is removed by the planarization process; and
forming a conductive feature electrically coupling to the metal via.

2. The method of claim 1, wherein the planarization process results in the metal via to be revealed.

3. The method of claim 1, wherein the composite die comprises an adhesion film between the sacrificial carrier and the metal via, and wherein the adhesion film is further removed by the planarization process.

4. The method of claim 1, wherein the composite die further comprises a dielectric layer, and wherein the metal via is in the dielectric layer.

5. The method of claim 4, wherein a first top surface of the dielectric layer is coplanar with a second top surface of the metal via.

6. The method of claim 1, wherein at a time the planarization process is started, a bottommost surface of the sacrificial carrier is higher than the metal via.

7. The method of claim 1, wherein the composite die further comprises a through-via penetrating through the semiconductor substrate, wherein the metal via is over the through-via.

8. The method of claim 7, wherein the metal via is in contact with the through-via.

9. The method of claim 1 further comprising thinning the sacrificial carrier before the composite die is encapsulated in the encapsulant.

10. The method of claim 1, wherein the metal via is on a front side of the semiconductor substrate.

11. The method of claim 1 further comprising:
forming a plurality of metal posts, wherein the encapsulant further encapsulates the plurality of metal posts therein, and wherein the planarization process further results in the plurality of metal posts to be revealed.

12. The method of claim 1 further comprising:
attaching the sacrificial carrier to a device wafer comprising the metal via therein to form a composite wafer; and
sawing the composite wafer as a plurality of composite dies, with the composite die being one of the plurality of composite dies.

13. A method comprising:
forming a redistribution structure over a carrier, the redistribution structure comprising:
a plurality of dielectric layers; and
a plurality of redistribution lines in the plurality of dielectric layers;
bonding a composite die to the redistribution structure, the composite die comprising:
a semiconductor substrate;
a through-via in the semiconductor substrate;
a metal via electrically coupled to the through-via; and
a sacrificial carrier attached to the metal via; and
performing a planarization process to remove the sacrificial carrier, wherein the metal via is revealed by the planarization process.

14. The method of claim 13, wherein the composite die further comprises a dielectric layer, and wherein the metal via is in the dielectric layer.

15. The method of claim 14, wherein the dielectric layer is revealed by the planarization process.

16. The method of claim 13 further comprising forming the composite die comprising:
performing a backside thinning process to thin the semiconductor substrate and to reveal the through-via;
recessing the semiconductor substrate, so that a protruding portion of the through-via protrudes out of the semiconductor substrate; and
forming a dielectric isolation layer to encircle the protruding portion of the through-via.

17. The method of claim 13, wherein the metal via laterally extends beyond respective edges of the through-via.

18. A method comprising:
forming a package comprising:
forming a redistribution structure; and
bonding a composite die over the redistribution structure, wherein the composite die comprises:
a semiconductor substrate;
a through-via in the semiconductor substrate; and
a metal via contacting the through-via, wherein the metal via comprise edges extending laterally beyond respective edges of the through-via;
molding the composite die in a molding compound, wherein a top portion of the molding compound overlaps the composite die;
performing a planarization process to remove the top portion of the molding compound; and
continuing the planarization process on the composite die and the molding compound until the metal via is revealed.

19. The method of claim 18, wherein the composite die comprises a sacrificial carrier, and wherein the sacrificial carrier is also removed by the planarization process.

20. The method of claim 19, wherein the composite die comprises an adhesion film between the sacrificial carrier and the metal via, and wherein the adhesion film is also removed by the planarization process.
